(19) United States
(12) Patent Application Publication
(10) Pub. No.: US 2025/0133733 A1
(43) Pub. Date: Apr. 24, 2025

(54) SEMICONDUCTOR DEVICE AND METHOD OF MANUFACTURING THE SAME

(71) Applicant: Samsung Electronics Co., Ltd., Suwon-si (KR)

(72) Inventors: Hyesung PARK, Suwon-si (KR); Jonghyuk PARK, Suwon-si (KR); Seungji KANG, Suwon-si (KR); Seongeun KIM, Suwon-si (KR); Jinwoo BAE, Suwon-si (KR); Dongwon LEE, Suwon-si (KR); Juyeon HAN, Suwon-si (KR)

(73) Assignee: Samsung Electronics Co., Ltd., Suwon-si (KR)

(21) Appl. No.: 18/886,045

(22) Filed: Sep. 16, 2024

(30) Foreign Application Priority Data
Oct. 20, 2023 (KR) 10-2023-0141403

(51) Int. Cl. H10B 12/00

(52) U.S. Cl. CPC H10B 12/50; H10B 12/09; H10B 12/315

(57) ABSTRACT

A semiconductor device may include a substrate with a memory cell area including a first active area and a peripheral circuit area including a second active area, a capacitor structure including a first electrode connected to the first active area in the memory cell area, a second electrode including a silicon containing layer surrounding the first electrode on the memory cell area and a metal plate layer on the silicon containing layer, an interlayer insulating layer on the peripheral circuit area, and a capping insulating layer covering the capacitor structure on the memory cell area and covering the interlayer insulating layer on the peripheral circuit area. The capacitor structure may include a capacitor dielectric layer between the first and second electrode. The metal plate layer may be on an upper surface of the silicon containing layer and may not be on a side surface of the silicon containing layer.

### CROSS-REFERENCE TO RELATED APPLICATION

This application is based on and claims priority under 35 U. S. C. § 119 to Korean Patent Application No. 10-2023-0141403, filed on Oct. 20, 2023 in the Korean Intellectual Property Office, the disclosure of which is incorporated by reference herein in its entirety.

### BACKGROUND

Inventive concepts relate to a semiconductor device and/or a manufacturing method thereof, and more particularly, to a semiconductor device including a capacitor and/or a method of manufacturing the semiconductor device.

According to the development of electronic industry and users' needs, down-scaling of semiconductor devices have been rapidly proceeded. Accordingly, the areas of unit cells included in the semiconductor devices have been reduced, thereby reducing the areas that can be occupied by capacitors in the unit cells. Therefore, it is necessary to develop a semiconductor device having a structure in which a required capacitance is obtained to maintain desired electrical characteristics, even when the size of a capacitor is miniaturized.

### SUMMARY

Inventive concepts provide a semiconductor device having an improved productivity and/or structural reliability.

According to an embodiment of inventive concepts, a semiconductor device may include a substrate including a memory cell area with a first active area and a peripheral circuit area with a second active area; a capacitor structure including a first electrode connected to the first active area in the memory cell area, a second electrode including a silicon containing layer surrounding the first electrode on the memory cell area, and a metal plate layer on the silicon containing layer, and a capacitor dielectric layer between the first electrode and the second electrode; an interlayer insulating layer on the peripheral circuit area; and a capping insulating layer covering the capacitor structure on the memory cell area and covering the interlayer insulating layer on the peripheral circuit area. The metal plate layer may be on an upper surface of the silicon containing layer and the metal plate layer may not be on a side surface of the silicon containing layer.

According to an embodiment of inventive concepts, a semiconductor device may include a substrate including a memory cell area with a first active area and a peripheral circuit area with a second active area; a capacitor structure including a first electrode connected to the first active area in the memory cell area, a second electrode including a silicon containing layer surrounding the first electrode on the memory cell area and a metal plate layer on the silicon containing layer, and a capacitor dielectric layer between the first electrode and the second electrode; an interlayer insulating layer on the peripheral circuit area; and a capping insulating layer covering the capacitor structure on the memory cell area and covering the interlayer insulating layer on the peripheral circuit area. An upper surface of the silicon containing layer and an upper surface of the interlayer insulating layer may be coplanar in a horizontal direction.

According to an embodiment of inventive concepts, a semiconductor device may include a substrate including a memory cell area with a first active area and a peripheral circuit area with a second active area; a capacitor structure including a first electrode connected to the first active area on the memory cell area, a second electrode including a silicon germanium layer surrounding the first electrode on the memory cell area and a metal plate layer on the silicon germanium layer, and a capacitor dielectric layer between the first electrode and the second electrode; an interlayer insulating layer on the peripheral circuit area and covering a side surface of the capacitor structure; and a capping insulating layer covering the capacitor structure on the memory cell area and covering the interlayer insulating layer on the peripheral circuit area. The metal plate layer may be on an upper surface of the silicon germanium layer and the metal plate layer may not be on a side surface of the silicon germanium layer. The upper surface of the silicon germanium layer and an upper surface of the metal plate layer may be coplanar.

### BRIEF DESCRIPTION OF THE DRAWINGS

Embodiments will be more clearly understood from the following detailed description taken in conjunction with the accompanying drawings in which:

FIG. 1 is a layout diagram of a semiconductor device according to embodiments;

FIG. 2 is an enlarged view of region EX1 of FIG. 1;

FIG. 3 is a cross-sectional view of the semiconductor device taken along line A-A′ of FIG. 2;

FIG. 4 is a cross-sectional view of the semiconductor device according to some embodiments;

FIG. 5 is a cross-sectional view of the semiconductor device according to some embodiments; and

FIGS. 6 to 18 are cross-sectional views of the semiconductor device for explaining a method of manufacturing the semiconductor device, according to some embodiments.

### DETAILED DESCRIPTION OF THE EMBODIMENTS

Hereinafter, embodiments of inventive concepts will be described in detail with reference to the accompanying drawings. Same reference numerals are used for same components in the drawings, and repeated description thereof will be omitted.

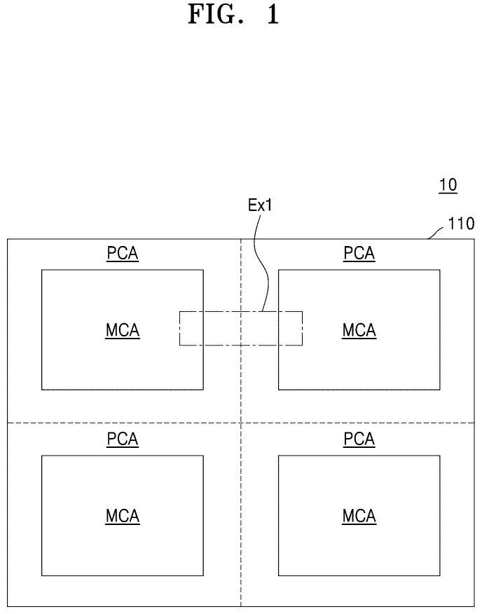

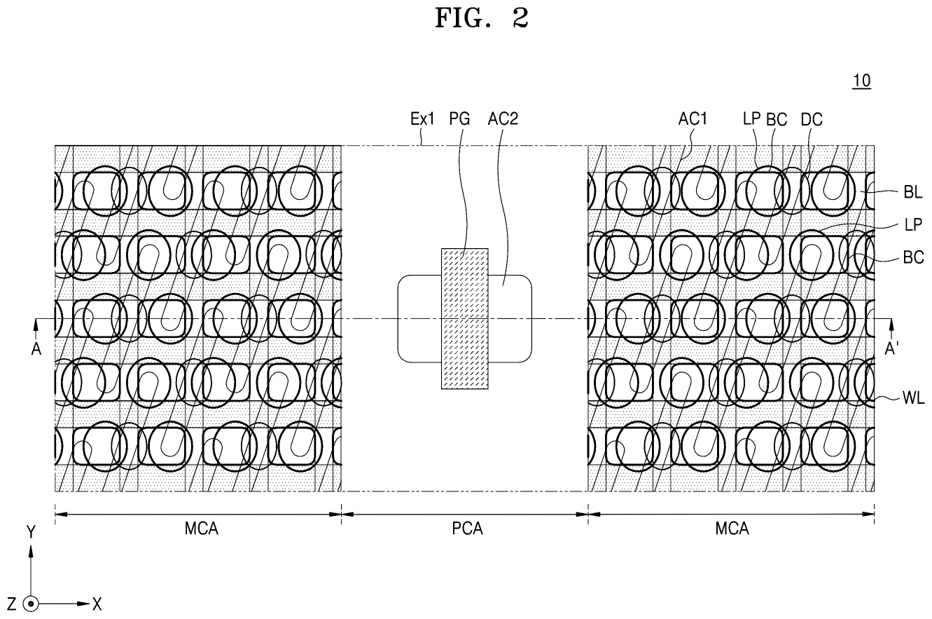

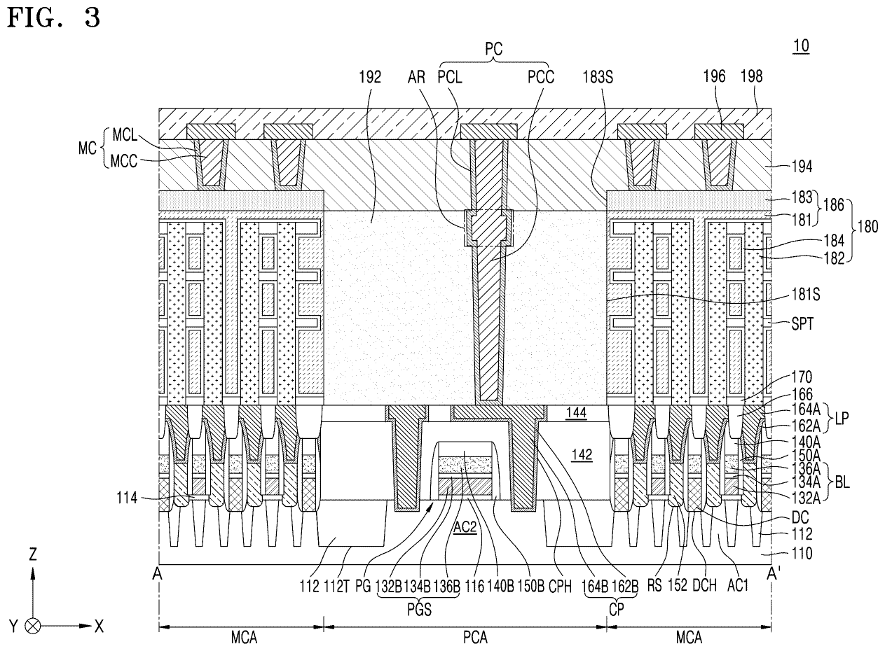

FIG. 1 is a layout diagram of a semiconductor device 10 according to embodiments. FIG. 2 is an enlarged view of region EX1 of FIG. 1. FIG. 3 is a cross-sectional view of the semiconductor device 10 taken along line A-A′ of FIG. 2.

Referring to FIGS. 1 to 3, the semiconductor device 10 may include a substrate 110 including a memory cell area MCA and a peripheral circuit area PCA surrounding the memory cell area MCA.

The memory cell area MCA may be a memory cell area of a dynamic random access memory (DRAM). The memory cell area MCA may include a plurality of unit memory cells each including a transistor and a capacitor. The peripheral circuit area PCA may be a core area or a peripheral circuit area of the DRAM. The peripheral circuit area PCA may be an area in which peripheral circuits for driving memory cells in the memory cell area MCA are arranged. For example, the peripheral circuit area PCA may include a peripheral circuit transistor PG including in the memory cell area MCA and configured to transmit signals and/or power to the memory cell area MCA. In an embodiment, the peripheral circuit transistor PG may be included in various circuits such as a command decoder, a control logic, an address buffer, a row decoder, a column decoder, a sense amplifier, and a data input/output circuit.

The substrate 110 may include a device isolating trench 112T and the device isolating trench 112T may include a device isolation layer 112. The device isolation layer 112 may include an oxide layer, a nitride layer, or a combination thereof. By the device isolation layer 112, a plurality of first active areas AC1 may be defined on the substrate 110 in the memory cell area MCA and a second active area AC2 may be defined on the substrate 110 in the peripheral circuit area PCA.

The plurality of first active areas AC1 may be arranged in the memory cell area MCA to have a long axis in a diagonal direction with respect to a first horizontal direction (an X direction) and a second horizontal direction (a Y direction). The plurality of word lines WL may extend across the plurality of first active areas AC1 and in parallel to the first horizontal direction (the X direction). A plurality of bit lines BL may extend in parallel with each other in the second horizontal direction (the Y direction) and above the plurality of word lines WL. The plurality of bit lines BL may be connected to the plurality of first active areas AC1 through a plurality of direct contacts DC.

A plurality of buried contacts BC may be formed between two adjacent bit lines BL among the plurality of bit lines BL. In some embodiments, the plurality of buried contacts BC may be arranged in a row along the first horizontal direction (the X direction) and the second horizontal direction (the Y direction). A plurality of landing pads LP may be arranged above the plurality of buried contacts BC. The plurality of buried contacts BC and the plurality of landing pads LP may connect a first electrode 182 of a capacitor structure 180 formed above the plurality of bit lines BL with a plurality of first active areas AC1. At least a portion of each of the plurality of landing pads LP may overlap the buried contact BC in the vertical direction (a Z direction).

The substrate 110 may include, for example, a semiconductor element such as silicon (Si), germanium (Ge) and at least one compound semiconductor selected from silicon germanium (SiGe), silicon carbide (SiC), gallium arsenide (GaAs), indium arsenide (InAs), and indium phosphide (InP). The substrate 110 may include a conductive area, for example, a well doped with impurities or a structure doped with impurities.

In the memory cell area MCA, a plurality of word line trenches (not shown) extending in the first horizontal direction (the X direction) may be formed on the substrate 110, and a plurality of gate dielectric layers (not shown), a plurality of gate electrodes (not shown), and a plurality of capping insulating layers (not shown) may be formed in the plurality of word line trenches. The plurality of gate electrodes may correspond to the plurality of word lines WL illustrated in FIG. 1. The plurality of gate dielectric layers may include Si oxide, Si nitride, Si oxynitride, oxide/nitride/oxide (ONO), or a high-k dielectric material having a higher dielectric constant than Si oxide. The plurality of gate electrodes may include titanium (Ti), titanium nitride (TiN), tantalum (Ta), tantalum nitride (TaN), tungsten (W), tungsten nitride (WN), titanium silicon nitride (TiSiN), tungsten silicon nitride (WSiN), or a combination thereof. The plurality of capping insulating layers may include a Si oxide layer, a Si nitride layer, a Si oxynitride layer, or a combination thereof.

In the memory cell area MCA, a buffer layer 114 may be disposed on the substrate 110. The buffer layer 114 may include an oxide layer, a nitride layer, or a combination thereof.

A plurality of direct contacts DC may be formed in a plurality of direct contact holes DCH of the substrate 110. The direct contact DC may extend above a higher level than an upper surface of the substrate 110. The plurality of direct contacts DC may be connected to the plurality of first active areas AC1. The plurality of direct contacts DC may include Si, Ge, W, WN, Co, Ni, Al, Mo, Ru, Ti, TiN, Ta, TaN, or a combination thereof. In some embodiments, the plurality of direct contacts DC may each include doped polysilicon. For example, the plurality of direct contacts DC may include polysilicon including a relatively high concentration of impurities such as phosphorus (P), arsenic (As), bismuth (Bi), and antimony (Sb).

The plurality of bit lines BL may extend along the second horizontal direction (the Y direction) in parallel to each other on each of the substrate 110 and the plurality of direct contacts DC. The plurality of bit lines BL may be respectively connected to the plurality of first active areas AC1 through the plurality of direct contacts DC. The plurality of bit lines BL may each include a lower conductive layer 132A, an intermediate conductive layer 134A, and an upper conductive layer 136A that are sequentially stacked on the substrate 110. The upper surface of the lower conductive layer 132A may be arranged at the same vertical level as the upper surface of the direct contact DC, and the bottom surface of the intermediate conductive layer 134a may be in contact with the upper surface of the direct contact DC.

The lower conductive layer 132A may include doped polysilicon. The intermediate conductive layer 134A and the upper conductive layer 136A may each include Ti, TiN, TiSiN, W, WN, tungsten silicide (WSiₓ), tungsten silicon nitride (WSiₓN_{y}), Ru, or a combination thereof. For example, the intermediate conductive layer 134A may include a TiN layer and/or TiSiN and the upper conductive layer 136A may include a layer including Ti, TiN, W, WN, WSiₓN_{y}, Ru, or a combination thereof.

In FIG. 3 illustrates that the plurality of bit lines BL each have a triple conductive layer structure including the lower conductive layer 132A, the intermediate conductive layer 134a, and the upper conductive layer 136a, but inventive concepts are not limited thereto. For example, the plurality of bit lines BL may have a structure including a single conductive layer or a stacked structure including double conductive layers or a plurality of four or more conductive layers.

The upper surfaces of the plurality of bit lines BL may be respectively covered with a plurality of insulating capping layers 140A. The plurality of insulating capping layers 140a may be respectively disposed on the upper conductive layer 136A of the plurality of bit lines BL. The plurality of insulating capping layers 140A may respectively extend in the second horizontal direction (the Y direction) on the plurality of bit lines BL. The plurality of insulating capping layers 140A may each include a Si nitride layer.

Insulating spacers 150A may be arranged in both side walls of each of the plurality of bit lines BL and each of the plurality of insulating capping layers 140A. The insulating spacer 150A may extend in the second horizontal direction (the Y direction) on both side walls of the plurality of bit lines BL. Some of the insulating spacers 150A may further extend into the direct contact hole DCH and cover both side walls of the direct contact DC formed in the direct contact hole DCH.

In some areas of the substrate 110, a plurality of recess spaces RS formed in the first active area AC1 may be respectively filled with a plurality of contact plugs 152. The plurality of contact plugs 152 may respectively extend along the vertical direction (the Z direction) from the recess spaces RS. Each of the plurality of contact plugs 152 may be in contact with the first active area AC1. The plurality of contact plugs 152 may be arranged in a row along the second horizontal direction (the Y direction) between each of the plurality of bit lines BL. The plurality of contact plugs 152 may be included in the plurality of buried contacts BC illustrated in FIG. 2. The plurality of contact plugs 152 may include impurity-doped semiconductor patterns but are not limited thereto.

A plurality of insulating fences (not shown) may be arranged between each of the plurality of contact plugs 152 arranged in a row along the second horizontal direction (the Y direction). The plurality of contact plugs 152 may be insulated from each other by the plurality of insulating fences (not shown). In some embodiments, the plurality of insulating fences (not shown) may include Si nitride layers.

The plurality of landing pads LP may be arranged above the plurality of contact plugs 152. The plurality of landing pads LP may respectively extend along the vertical direction (the Z direction) on the contact plugs 152. Each of the plurality of landing pads LP may include a conductive barrier layer 162A and a landing pad conductive layer 164A. In some embodiments, the conductive barrier layer 162a may include Ti, TiN, or a combination thereof, and the landing pad conductive layer 164A may include metal, metal nitride, conductive polysilicon, or a combination thereof. The plurality of landing pads LP may have a planar Irish pattern shape. The plurality of landing pads LP may be electrically insulated from each other by insulating patterns 166 respectively surrounding the plurality of landing pads LP.

Metal silicide layers (not shown) may be further be arranged between the plurality of contact plugs 152 and the plurality of landing pads LP. The metal silicide layer may include, for example, cobalt silicide, nickel silicide, or manganese silicide.

In the peripheral circuit area PCA, the peripheral circuit transistor PG may be disposed on the second active area AC2. The peripheral circuit transistor PG may include a gate dielectric layer 116, a gate electrode PGS, and a gate capping layer 140B that are sequentially stacked on the second active area AC2.

The gate dielectric layer 116 may include at least one selected from Si oxide, Si nitride, Si oxynitride, or a high-k dielectric material having a higher dielectric constant than that of Si oxide.

The gate electrode PGS may include a lower conductive layer 132B, an intermediate conductive layer 134B, and an upper conductive layer 136B. The materials included in the lower conductive layer 132B, the intermediate conductive layer 134B, and the upper conductive layer 136B may be the same or substantially the same as the materials included in the lower conductive layer 132A, the intermediate conductive layer 134A, and the upper conductive layer 136A included in the bit line BL arranged in the memory cell area MCA, respectively.

The gate capping layer 140B may include, for example, Si nitride.

In some embodiments, both side walls of the gate electrode PGS may be respectively covered with gate spacers 150B. The gate spacer 150B may include, for example, Si oxide, Si nitride, or a combination thereof.

The peripheral circuit transistor PG may be covered with a first insulating layer 142. A second insulating layer 144 may be disposed on the first insulating layer 142. In the peripheral circuit area PCA, a contact plug CP may be formed in a contact hole CPH penetrating through the first insulating layer 142 and the second insulating layer 144 in the vertical direction (the Z direction). The contact plug CP may include a conductive barrier layer 162B and a plug conductive layer 164B. The conductive barrier layer 162B and the plug conductive layer 164B of the contact plug CP may have structures that are substantially the same as or similar to those of the conductive barrier layer 162A and the landing pad conductive layer 164A of the plurality of landing pads LP formed in the memory cell area MCA, and may include the same or substantially the same material as those of the conductive barrier layer 162A and the landing pad conductive layer 164A of the plurality of landing pads LP formed in the memory cell area MCA.

An upper insulating pattern 170 may be disposed on the insulating pattern 166 in the memory cell area MCA. The upper insulating pattern 170 may include a material having an etching selectivity with respect to the second insulating layer 144 and the insulating pattern 166. For example, the upper insulating pattern 170 may include Si nitride.

The capacitor structure 180 may be disposed on the upper insulating pattern 170 in the memory cell area MCA. The capacitor structure 180 may include the plurality of first electrodes 182, a capacitor dielectric layer 184, and a second electrode 186. The capacitor structure 180 may only be formed in the memory cell area MCA. That is, the plurality of first electrodes 182, the capacitor dielectric layer 184, and the second electrode 186 of the capacitor structure 180 may not be formed in the peripheral circuit area PCA.

The plurality first electrodes 182 may be arranged above the plurality of landing pads LP. The plurality of first electrodes 182 may penetrate through the upper insulating pattern 170 and extend in the vertical direction (the Z direction) on the plurality of landing pads LP. The bottom surface of the plurality of first electrodes 182 may be in contact with one landing pad LP selected from the plurality of landing pads LP. The plurality of first electrodes 182 may be in contact with and thus be connected to the landing pad LP. The plurality of first electrodes 182 may each include metal, conductive metal oxide, conductive metal nitride, conductive metal oxynitride, or a combination thereof. In some embodiments, the plurality of first electrodes 182 may each include Ti, Ti oxide, TiN, Ti oxynitride, Co, Co oxide, Co nitride (CoN), Co silicide, Nb, Nb oxide, Nb nitride (NbN), Nb oxynitride, Sn, Sn dioxide (SnO₂), Sn nitride, Sn oxynitride, or a combination thereof. For example, the plurality of first electrodes 182 may each include TiN, CoN, NbN, SnO₂, or a combination thereof, but are not limited thereto.

A plurality of support layers SPT may be on the side walls of the plurality of first electrodes 182. The plurality of support layers SPTs may maintain a certain distance between two adjacent first electrodes 182 and may limit and/or prevent the plurality of first electrodes 182 from being tilted or collapsed. The plurality of support layers SPT may be arranged at different vertical levels on the side walls of the plurality of first electrodes 182.

The capacitor dielectric layer 184 may be arranged between each of the plurality of first electrodes 182, plurality of support layers SPT, and upper insulating pattern 170 and a Si-containing layer 181. The capacitor dielectric layer 184 may cover the side walls of the plurality of first electrodes 182, the upper surface and bottom surface of the support layer SPT, and the upper surface of the upper insulating pattern 170. The capacitor dielectric layer 184 may include zirconium oxide, hafnium oxide, titanium oxide, Nb oxide, Ta oxide, yttrium oxide, strontium Ti oxide, barium strontium Ti oxide, scandium oxide, lanthanide oxide, or a combination thereof.

The second electrode 186 may include the Si-containing layer 181 and a metal plate layer 183. The Si-containing layer 181 may be above the capacitor dielectric layer 184 and surround the plurality of first electrodes 182. A side surface 181S of the Si-containing layer 181 may be in contact with an interlayer insulating layer 192. The Si-containing layer 181 may include, for example, Si-germanium, but are not limited thereto, and the Si-containing layer 181 may include, for example, polysilicon. In some embodiments, an upper surface of the Si-containing layer 181 may be a flat surface planarized by a planarization process.

The metal plate layer 183 may be disposed on the upper surface of the Si-containing layer 181. In some embodiments, the metal plate layer 183 may be disposed only on the upper surface of the Si-containing layer 181. That is, the metal plate layer 183 may not be disposed on the side surface 181S of the Si-containing layer 181. A side surface 183S of the metal plate layer 183 may be covered by a capping insulating layer 194. The side surface 183S of the metal plate layer 183 may be arranged on the same plane as the side surface 181S of the Si-containing layer 181 in the vertical direction. The metal plate layer 183 may include, for example, W, but are not limited thereto.

By using the Si-containing layer 181 and the metal plate layer 183 as the second electrode 186 of the capacitor structure 180, a sensing margin in the capacitor structure 180 may be secured.

In the peripheral circuit area PCA, the interlayer insulating layer 192 may be disposed on the second insulating layer 144 and the contact plug CP. The interlayer insulating layer 192 may cover the second insulating layer 144 and contact plug CP. The interlayer insulating layer 192 may fill a space between the capacitor structures 180 respectively included in two adjacent memory cell areas MCA. Accordingly, the interlayer insulating layer 192 may cover the side surface 181S of the Si-containing layer 181. The bottom surface of the interlayer insulating layer 192 may be arranged at the same vertical level as the bottom surface of the plurality of first electrodes 182. The upper surface of the interlayer insulating layer 192 may be arranged on the same plane as the upper surface of the Si-containing layer 181 in the horizontal direction. Accordingly, the interlayer insulating layer 192 may not be in contact with the metal plate layer 183. In some embodiments, the upper surface of the interlayer insulating layer 192 may be a flat surface planarized by a planarization process.

The capping insulating layer 194 may be disposed on the metal plate layer 183 in the memory cell area MCA and on the interlayer insulating layer 192 in the peripheral circuit area PCA. The capping insulating layer 194 may have different lengths in the vertical direction in the memory cell area MCA and the peripheral circuit area PCA to cover a step difference between the memory cell area MCA and the peripheral circuit area PCA. For example, a portion of the capping insulating layer 194 in the peripheral circuit area PCA may have a greater length in the vertical direction than the remaining portion of the capping insulating layer 194 in the memory cell area MCA. A portion of the capping insulating layer 194 in the peripheral circuit area PCA may cover the side surface 183S of the metal plate layer 183 and the upper surface of the interlayer insulating layer 192, and the remaining portion of the capping insulating layer 194 in the memory cell area MCA may cover the upper surface of the metal plate layer 183.

In some embodiments, the interlayer insulating layer 192 and the capping insulating layer 194 may each include oxide. For example, the interlayer insulating layer 192 and the capping insulating layer 194 may each include tetraethyl orthosilicate (TEOS), low deposition-tetraethyl orthosilicate (LD-TEOS), plasma enhanced-tetraethyl orthosilicate (PE-TEOS), or a combination thereof. In some embodiments, the interlayer insulating layer 192 and the capping insulating layer 194 may include different materials from each other. For example, the interlayer insulating layer 192 may include LD-TEOS material and the capping insulating layer 194 may include TEOS material.

A plurality of cell contacts MC may penetrate through the capping insulating layer 194 to extend in the vertical direction (the Z direction) in the memory cell area MCA. The bottom surface of the plurality of cell contacts MC may be in contact with and thus be connected to the metal plate layer 183. The plurality of cell contacts MC may each include a cell conductive barrier layer MCL and a cell contact conductive layer MCC. The plurality of cell contacts MC may have a planar circular shape.

The peripheral circuit contact PC may penetrate through the capping insulating layer 194 and the interlayer insulating layer 192 to extend in the vertical direction (the Z direction) in the peripheral circuit area PCA. The peripheral circuit contacts PC may have a planar circular shape. The bottom surface of the peripheral circuit contact PC may be in contact with and thus be connected to the contact plug CP. The peripheral circuit contact PC may be connected to the second active area AC2 through the contact plug CP.

The peripheral circuit contact PC may include a peripheral circuit conductive barrier layer PCL and a peripheral circuit contact conductive layer PCC. The peripheral circuit contact conductive layer PCC may partially protrude in the horizontal direction in an adjacent area AR adjacent to a boundary between the interlayer insulating layer 192 and the capping insulating layer 194. In this case, the adjacent area AR may be adjacent to the boundary between the interlayer insulating layer 192 and the capping insulating layer 194 and below the boundary (that is, an area inside the interlayer insulating layer 192) in the drawing. Accordingly, a horizontal width of the peripheral circuit contact conductive layer PCC in the adjacent area (AR) may be greater than the horizontal width of the peripheral circuit contact conductive layer PCC in the remaining areas excluding the adjacent area AR.

An upper wiring layer 196 and an interlayer insulating layer 198 covering the upper wiring layer 196 may be disposed on the plurality of cell contacts MC, the peripheral circuit contact PC, and the capping insulating layer 194. The bottom surface of the upper wiring layer 196 may be in contact with the upper surfaces of each of the plurality of cell contacts MC and the peripheral circuit contact PC.

In some embodiments, the upper wiring layer 196 may include W, Cu, Al, Co, Mo, Ru, Ti, Ta, TiN, TaN, or a combination thereof. For example, the upper wiring layer 196 may include a Cu layer. In some embodiments, the upper insulating layer 198 may include a low dielectric layer having a low dielectric constant K of about 2.2 to about 3.0. For example, the upper insulating layer 198 may include a SiOC layer or a SiCOH layer.

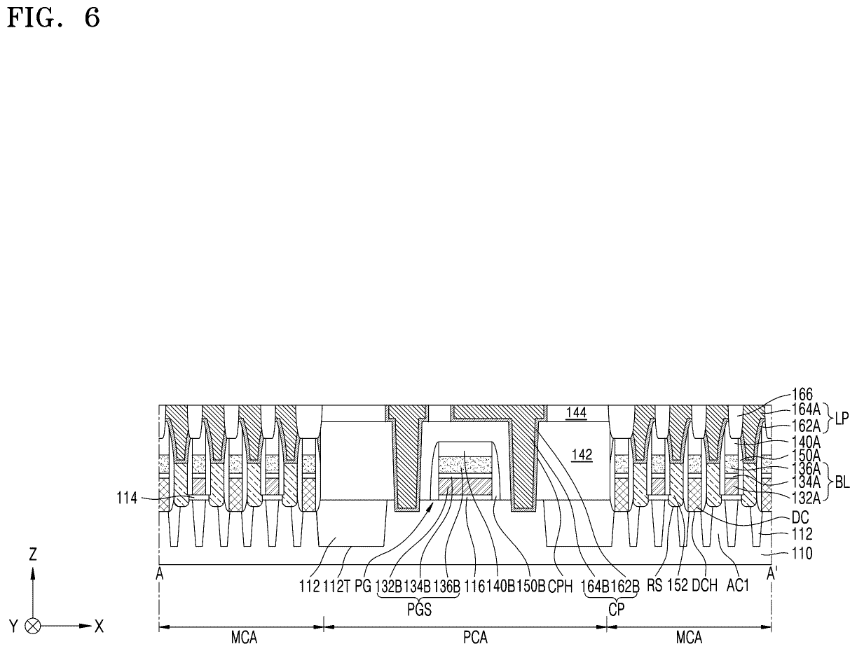

The semiconductor device 10 according to some embodiments may be manufactured, as described with reference to FIGS. 6 to 18, by forming the Si-containing layer 181 and a first insulating material layer 192P, planarizing the formed first insulating material layer 192P to form the interlayer insulating layer 192, forming the metal plate layer 183 on the Si-containing layer 181, and performing a subsequent process. Thus, the metal plate layer 183 of the semiconductor device 10 may be formed only on the upper surface of the Si-containing layer 181 and may not be formed on the side surface 181S of the Si-containing film 181. Accordingly, when the metal plate layer 183 is formed on the side surface 181S of the Si-containing layer 181, since an area occupied by the metal plate layer 183 formed on the side surface 181S may be reduced, the number of semiconductor devices 10 that may be manufactured in one wafer may be increased.

In addition, in the manufacturing process of the semiconductor device 10, since the first insulating material layer 192P covering the Si-containing layer 181 is formed before the metal plate layer 183 is formed and the interlayer insulating layer 192 is formed by planarizing the formed first insulating material layer 192P, the Si-containing layer 181 may act as an etch stop layer in the planarization process. Accordingly, a thickness variation of the interlayer insulating layer 192 formed by the planarization process may be improved without using a separate etch stop layer. Accordingly, the structural reliability of the semiconductor device 10 may be improved.

When the semiconductor device is manufactured by using a separate etch stop layer, after forming the metal plate layer 183 covering the Si-containing layer 181 and then forming the etch stop layer on the metal plate layer 183, the planarization process may be performed by using the etch stop layer to form the interlayer insulating layer 192. In this case, during the planarization process, poor adhesion between the etch stop layer and the metal plate layer 183 and a defect wherein a portion of the etch stop layer is torn off due to an outgassing of impurities generated in the planarization process may be caused. On the other hand, since the semiconductor device 10 according to some embodiments of is manufactured without a separate etch stop layer as described above, the tearing defect may be limited and/or prevented during the manufacturing process of the semiconductor device 10. Accordingly, the structural reliability of the semiconductor device 10 may be improved.

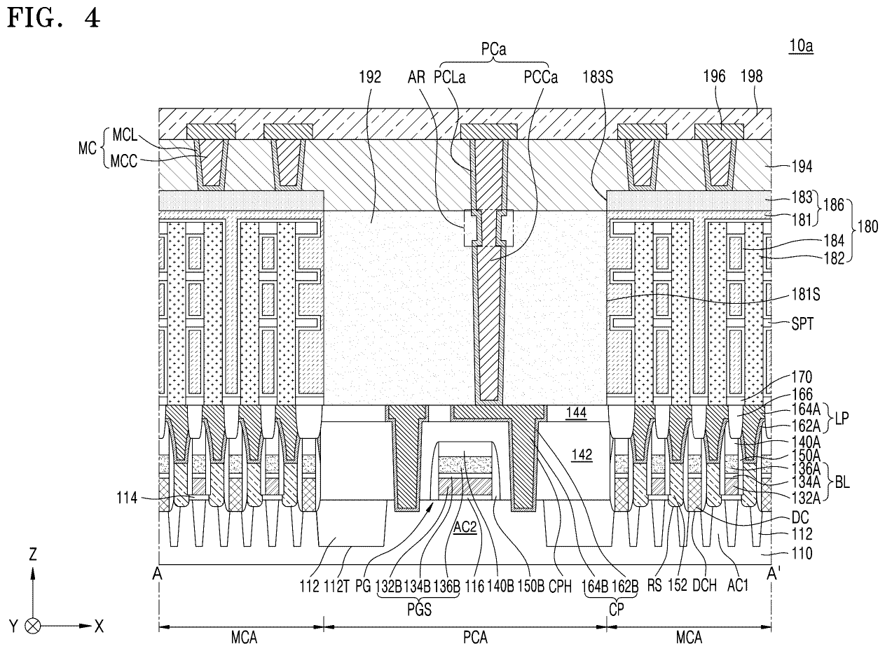

FIG. 4 is a cross-sectional view of a semiconductor device 10a according to some embodiments. Since each component of the semiconductor device 10a of FIG. 4 is substantially the same as or similar to each component of the semiconductor device 10 described with reference to FIGS. 1 to 3, differences thereof are mainly described below.

Referring to FIG. 4, except that the semiconductor device 10a includes a peripheral circuit contact PCa having a different structure from that of the peripheral circuit contact PC of the semiconductor device 10 illustrated in FIGS. 1 to 3, the semiconductor device 10a may include substantially the same or similar components as those of the semiconductor device 10.

The peripheral circuit contact PCa of the semiconductor device 10a may penetrate through the capping insulating layer 194 and the interlayer insulating layer 192 to extend in the vertical direction (the Z direction) in the peripheral circuit area PCA. The bottom surface of the peripheral circuit contact PCa may be in contact with and thus be connected to the contact plug CP.

The peripheral circuit contact PCa may include a peripheral circuit conductive barrier layer PCLa and a peripheral circuit contact conductive layer PCCa. The peripheral circuit contact conductive layer PCCa may be partially depressed in the horizontal direction in the adjacent area AR adjacent to the boundary between the interlayer insulating layer 192 and the capping insulating layer 194. Accordingly, a horizontal width of the peripheral circuit contact conductive layer PCCa in the adjacent area AR may be less than the horizontal width of the peripheral circuit contact conductive layer PCCa in the remaining areas excluding the adjacent area AR.

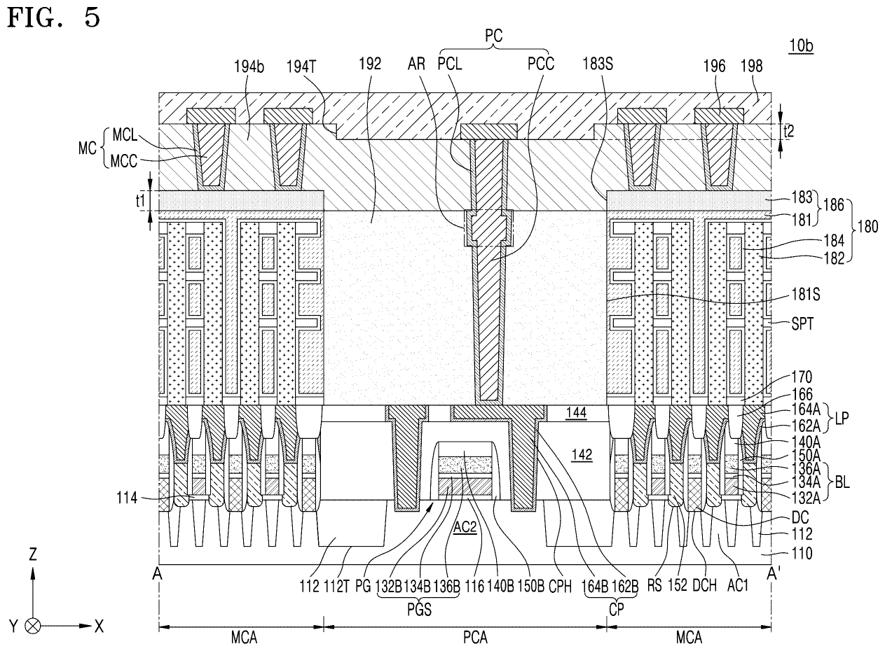

FIG. 5 is a cross-sectional view of a semiconductor device 10b according to some embodiments. Since each component of the semiconductor device 10b of FIG. 5 is substantially the same as or similar to each component of the semiconductor device 10 described with reference to FIGS. 1 to 3, differences thereof are mainly described below.

Referring to FIG. 5, except that the semiconductor device 10b includes an upper insulating layer 194b having a different structure from that of the capping insulating layer 194 of the semiconductor device 10 illustrated in FIGS. 1 to 3, the semiconductor device 10b may include substantially the same or similar components as those of the semiconductor device 10.

In the peripheral circuit area PCA, the capping insulating layer 194b of the semiconductor device 10b may include a trench 194T on the upper surface thereof. A vertical length t2 of the trench 194T may be the same or substantially the same as a vertical length t1 of the metal plate layer 183. By the trench 194T, the upper surface of the capping insulating layer 194b in the memory cell area MCA may be arranged on a higher vertical level than the upper surface of the capping insulating layer 194b in the peripheral circuit area PCA. That is, the upper surface of the capping insulating layer 194b may include a step difference having the same length as the vertical length t2 of the trench 194T between the memory cell area MCA and the peripheral circuit area PCA. The trench 194T of the capping insulating layer 194b may be filled with the upper insulating layer 198.

The upper surface of the peripheral circuit contact PC of the semiconductor device 10b may be arranged on a lower vertical level than the upper surface of the cell contact MC. This is because, in the manufacturing process of the semiconductor device 10b, the cell contact MC penetrating in the vertical direction (the Z direction) is formed in the memory cell area MCA and the peripheral circuit contact PC is formed in the peripheral circuit area PCA, without removing the step difference of the upper surface of the formed capping insulating layer 194b. In addition, since the upper surface of the peripheral circuit contact PC is located at a vertical level lower than the upper surface of the cell contact MC, the upper wiring layer 196 disposed on the peripheral circuit contact PC may be arranged on a vertical level lower than the upper wiring layer 196 disposed on the plurality of cell contacts MC.

FIGS. 6 to 18 are cross-sectional views of the semiconductor device 10 for explaining a method of manufacturing the semiconductor device 10, according to some embodiments. In particular, FIGS. 6 to 18 are cross-sectional views for describing operations of a method of manufacturing the semiconductor device 10, according to some embodiments.

Referring to FIG. 6, the plurality of device isolating trenches 112T may be formed on the substrate 110 including the memory cell area MCA and the peripheral circuit area PCA. Subsequently, a plurality of device isolation layers 112 may be formed by filling the device isolating trench 112T with isolation materials. By the plurality of device isolation layers 112, the plurality of first active areas AC1 may be defined in the memory cell area MCA of the substrate 110, and the second active area AC2 may be defined in the peripheral circuit area PCA.

Subsequently, the buffer layer 114 may be formed on the substrate 110 in the memory cell area MCA, and the gate dielectric layer 116 may be formed on the substrate 110 in the peripheral circuit area PCA.

Subsequently, a portion of the substrate 110 may be removed by using a mask pattern (not shown) to form the direct contact hole DCH. The direct contact hole DCH may expose the first active area AC1. The mask pattern may include, for example, an oxide layer, a nitride layer, or a combination thereof, but are not limited thereto. Thereafter, the direct contact DC may be formed by removing the mask pattern and filling a conductive material in the direct contact hole DCH.

Subsequently, in the memory cell area MCA, the lower conductive layer 132A, the intermediate conductive layer 134A, the upper conductive layer 136A, and the insulating capping layer 140A may be sequentially formed on the buffer layer 114 and the direct contact DC, and, in the peripheral circuit area PCA, the lower conductive layer 132B, the intermediate conductive layer 134B, the upper conductive layer 136B, and the insulating capping layer 140B may be sequentially formed on the peripheral circuit area PCA.

Subsequently, in the memory cell area MCA, the plurality of bit lines BL may be formed by etching a portion of each of the direct contact DC, the lower conductive layer 132A, the intermediate conductive layer 134A, and the upper conductive layer 136A by using the insulating capping layer 140A as an etching mask, and, in the peripheral circuit area PCA, the gate electrode PGS may be formed by etching a portion of each of the lower conductive layer 132B, the intermediate conductive layer 134B, and the upper conductive layer 136B by using the insulating capping layer 140B as an etching mask.

Subsequently, the insulating spacer 150B may be formed on the side wall of the gate electrode PGS, and the first insulating layer 142 covering the gate electrode PGS may be formed.

Next, in the memory cell region MCA, the insulating spacer 150A may be formed on the side walls of each of the plurality of bit lines BL and the insulating capping layers 140A, and a plurality of insulating fences (not shown) may be formed between the plurality of bit lines BL. The insulating spacer 150A may conformally cover the side walls of each of the plurality of bit lines BL and the insulating capping layers 140A.

Subsequently, a portion of the substrate 110 disposed on the bottom of a contact space (not shown) between the plurality of bit lines BL and between the plurality of insulating fences may be removed to form the plurality of recess spaces RS exposing the first active area AC1 between the plurality of bit lines BL. In some embodiments, an anisotropic etching process or a combination of an anisotropic etching process and an isotropic etching process may be used to form the plurality of recess spaces RS.

Subsequently, a plurality of recess spaces 152 and a portion of the contact space may be filled with a conductive material to form the plurality of contact plugs 152.

Subsequently, the plurality of contact holes CPH exposing the second active area AC2 may be formed by etching the first insulating layer 142 in the peripheral circuit area PCA.

Subsequently, the conductive barrier layer (not shown) and the conductive layer (not shown) covering a surface exposed on the substrate 110 may be formed in the memory cell area MCA and the peripheral circuit area PCA. Subsequently, by patterning the conductive barrier layer and the conductive layer, the plurality of landing pads LP including the conductive barrier layer 162A and the landing pad conductive layer 164A may be formed in the memory cell area MCA, and the plurality of contact plugs CP including the conductive barrier layer 162B and the plug conductive layer 162B may be formed in the peripheral circuit area PCA.

Subsequently, the insulating pattern 166 surrounding the side walls of the plurality of landing pads LP and the second insulating layer 144 covering the side wall of the contact plug CP may be formed.

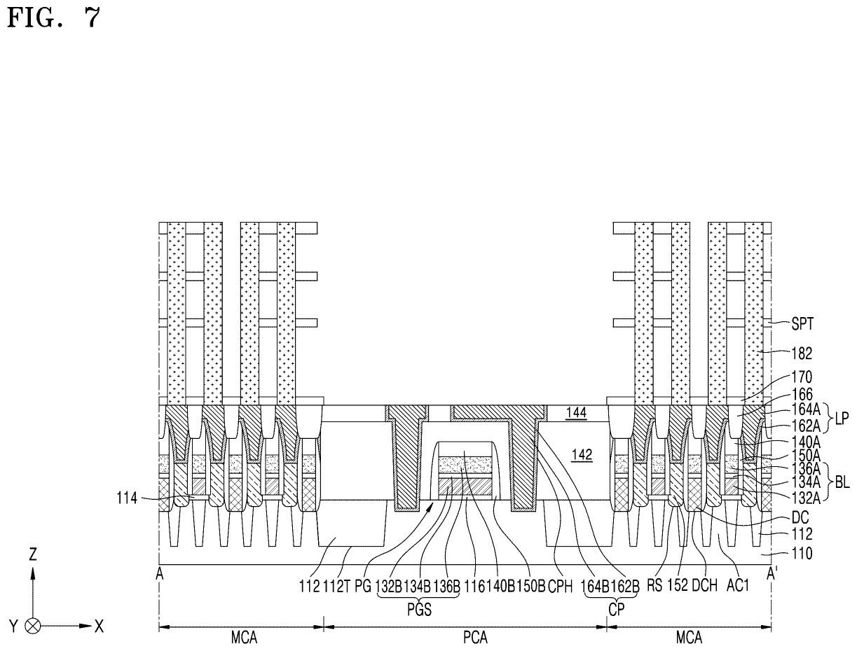

Referring to FIG. 7, the upper insulating pattern 170 may be formed on the insulating pattern 166 in the memory cell area MCA of the substrate 110. Subsequently, a mold structure (not shown) may be formed on the upper insulating pattern 170. The mold structure may include a first mold layer (not shown), a second mold layer (not shown), and a third mold layer (not shown) sequentially stacked on the upper insulating pattern 170.

In some embodiments, the support layer SPT may be optionally formed between the first mold layer and the second mold layer, between the second mold layer and the third mold layer, and on the third mold layer. Although an example wherein three support layers SPT are formed is illustrated in FIG. 7, inventive concepts are not limited thereto, and the number of the support layers SPT may differ according to the height of the plurality of first electrodes 182.

In some embodiments, the support layer SPT may be formed by using a material having an etching selectivity with respect to the material included in the mold structure. For example, the first mold layer to the third mold layer may be formed using Si oxide and the support layer SPT may be formed using Si nitride.

Subsequently, after forming a mask pattern (not shown) on the mold structure, an opening penetrating through the mold structure may be formed by using the pattern mask as an etching mask, and then the opening may be filled with a conductive material, thereby forming the plurality of first electrodes 182. Each of the bottom surfaces of the plurality of first electrodes 182 may be in contact with the upper surface of the conductive landing pad LP.

Subsequently, the mold structure may be removed in the memory cell area MCA, and the mold structure and the support layer SPT may be removed in the peripheral circuit area PCA. In the memory cell area MCA, the mold structure may be removed such that at least a portion of both side walls of the first electrodes 182, the lower surface and the upper surface of the support layer SPT, and the upper surface of the upper insulating pattern 170 may be exposed. In the peripheral circuit area PCA, the mold structure and the support layer SPT may be removed to expose the upper surface of the second insulating layer 144 and the upper surface of the contact plug CP.

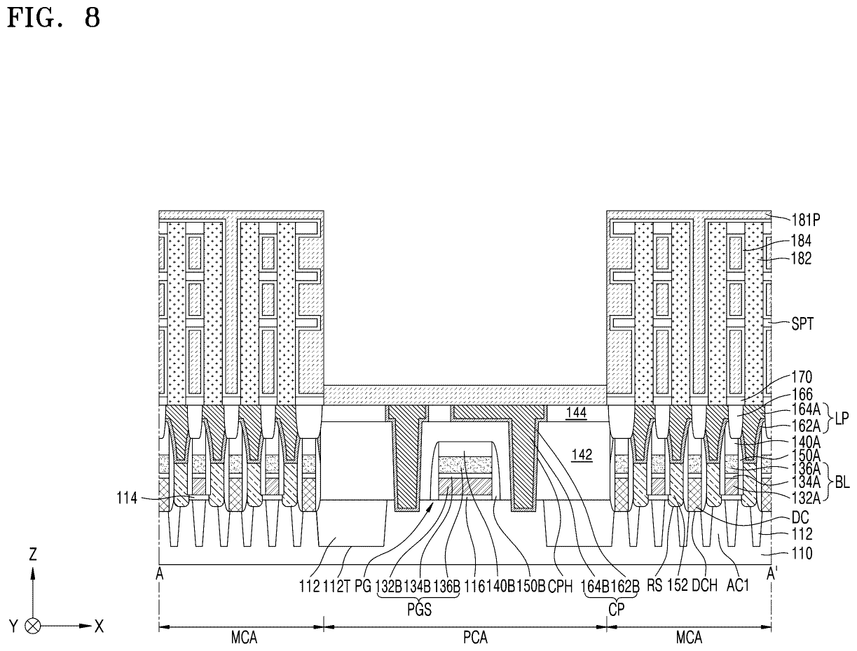

Referring to FIG. 8, the capacitor dielectric layer 184 may be formed on the upper insulating pattern 170, the plurality of first electrodes 182, and the support layer SPT. The capacitor dielectric layer 184 may be conformally cover the upper surface of the upper insulating pattern 170, at least a portion of both side walls of the first electrodes 182, and the upper surface and lower surface of the support layer SPT.

Next, a Si-containing material layer 181P covering the capacitor dielectric layer 184, the upper surface of the second insulating layer 144, and the upper surface of the contact plug CP may be formed. The Si-containing material layer 181P may include, for example, SiGe or polysilicon.

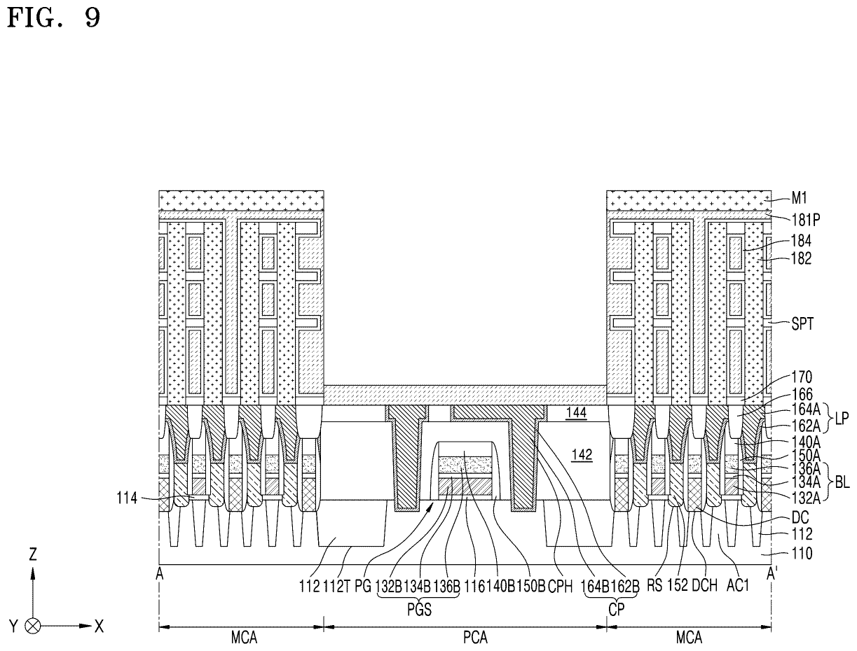

Referring to FIG. 9, a first mask pattern M1 may be formed on the upper surface of the Si-containing material layer 181P. The first mask pattern M1 may be, for example, a photoresist pattern including a photoresist material layer. The first mask pattern M1 may be formed on the upper surface of a portion of the Si-containing material layer 181P arranged in the memory cell area MCA and may not be formed in the remaining portion of the Si-containing material layer 181P arranged in the peripheral circuit area PCA.

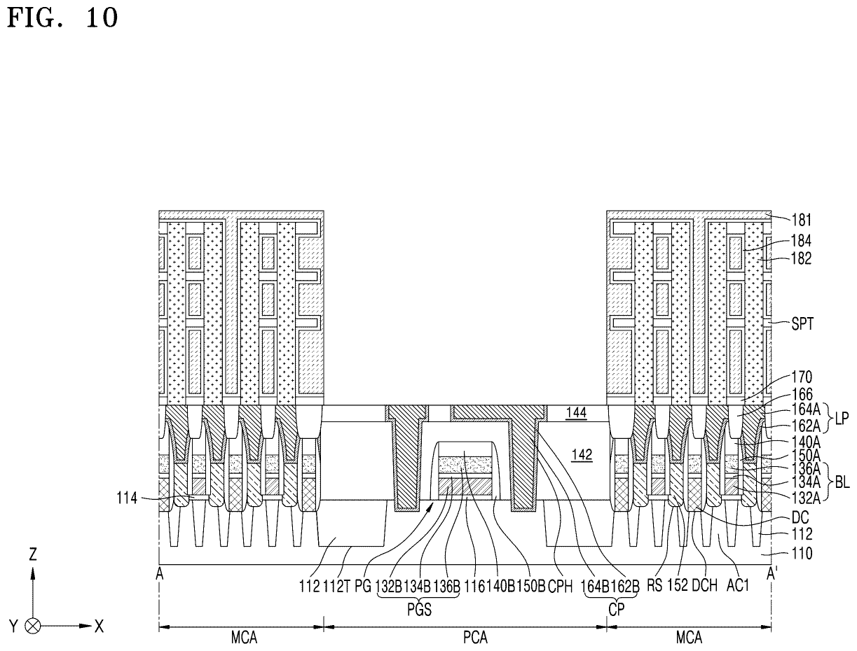

Referring to FIG. 10, the first mask pattern M1 (refer to FIG. 9) may be used as an etching mask to remove a portion of the Si-containing material layer 181P (refer to FIG. 9) arranged in the peripheral circuit area PCA. A portion of the Si-containing material layer 181P arranged in the peripheral circuit area PCA may be removed such that the upper surface of the second insulating layer 144 and the upper surface of the contact plug CP may be exposed. In addition, the Si-containing material layer 181P that is not removed and remains in the memory cell area MCA may be the Si-containing layer 181 included in the second electrode 186 of the capacitor structure 180.

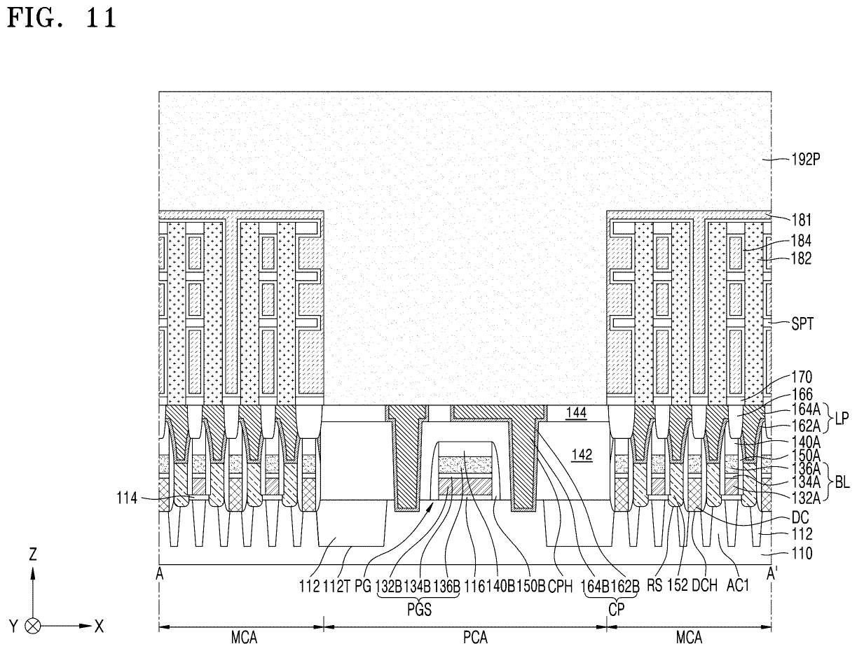

Referring to FIG. 11, a first insulating material layer 192P may cover the Si-containing layer 181 in the memory cell area MCA and cover the second insulating layer 144 and the contact plug CP in the peripheral circuit area PCA. The first insulating material layer 192P may be formed by a deposition process. In some embodiments, the first insulating material layer 192P may include TEOS, PE-TEOS, LD-TEOS, or a combination thereof.

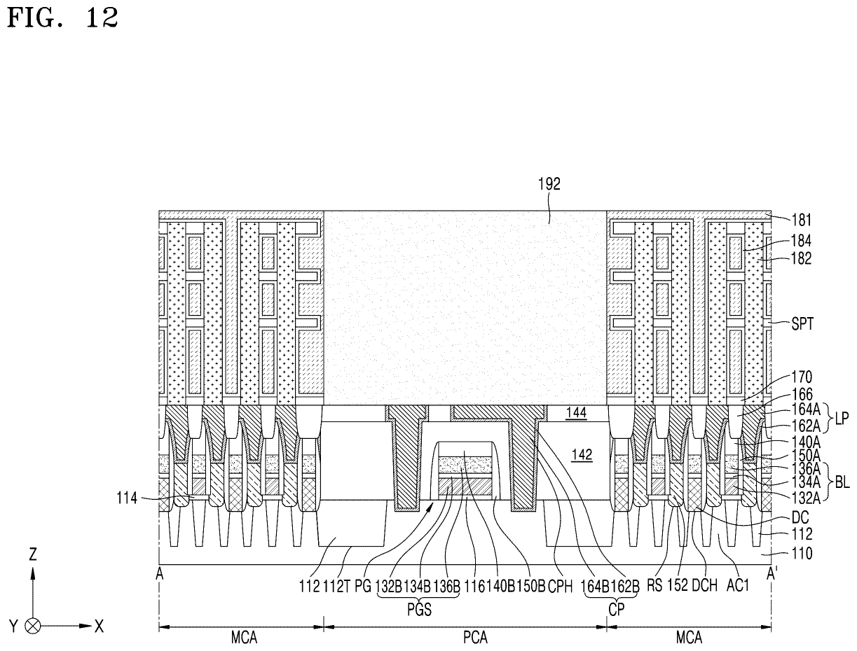

Referring to FIG. 12, the upper surface of the first insulating material layer 192P (refer to FIG. 11) may be planarized by the planarization process. The planarization process may be, for example, a chemical mechanical polishing (CMP) process. When performing the planarization process, the Si-containing layer 181 may act as an etch stop layer. Accordingly, the planarization process may be performed until the upper surface of the first insulating material layer 192P is arranged on the same plane as the upper surface of the Si-containing layer 181. A portion of the first insulating material layer 192P remaining without being removed after the planarization process is performed may be the interlayer insulating layer 192.

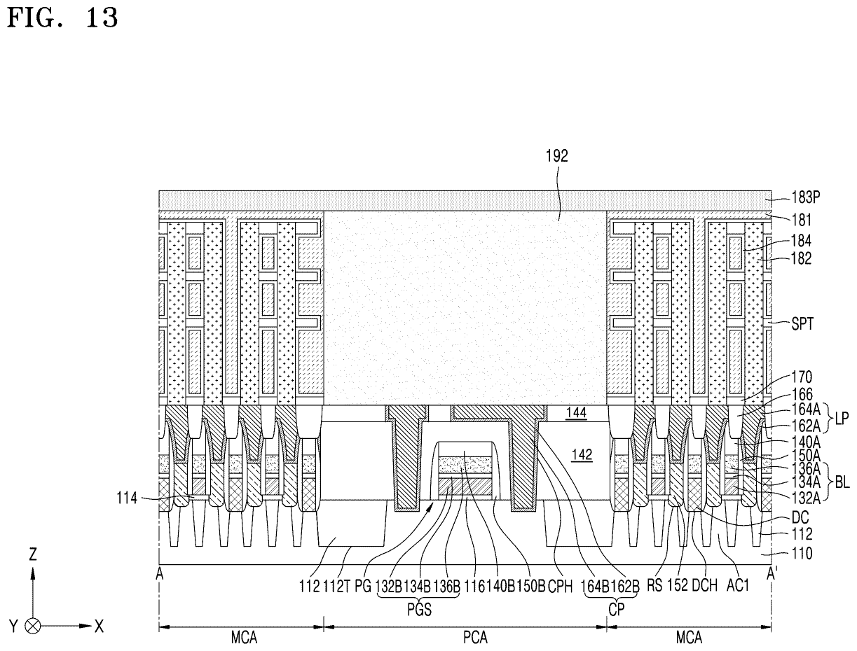

Referring to FIG. 13, a metal material layer 183P may be formed on the interlayer insulating layer 192 and the Si-containing layer 181. The metal material layer 183P may include, for example, W. The metal material layer 183P may completely cover the upper surface of the interlayer insulating layer 192 and the upper surface of the Si-containing layer 181.

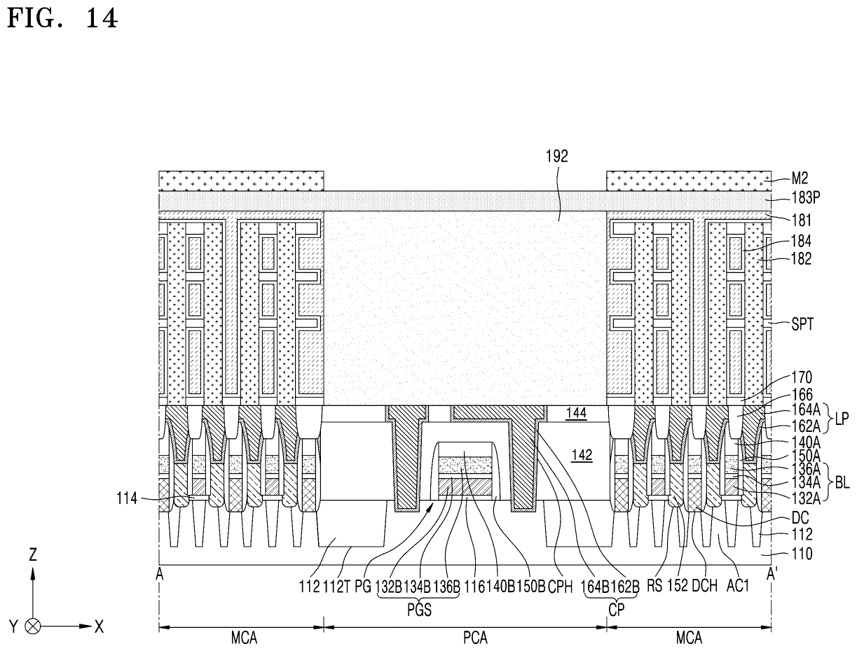

Referring to FIG. 14, a second mask pattern M2 may be formed on the metal material layer 183P. The second mask pattern M2 may be formed on a portion of the metal material layer 183P arranged in the memory cell area MCA, but may not be formed on the remaining portion of the metal material layer 183P arranged in the peripheral circuit area PCA. Accordingly, the remaining portion of the metal material layer 183P arranged in the peripheral circuit area PCA may be exposed by the second mask pattern M2. The second mask pattern M2 may be, for example, a photoresist pattern including a photoresist material layer.

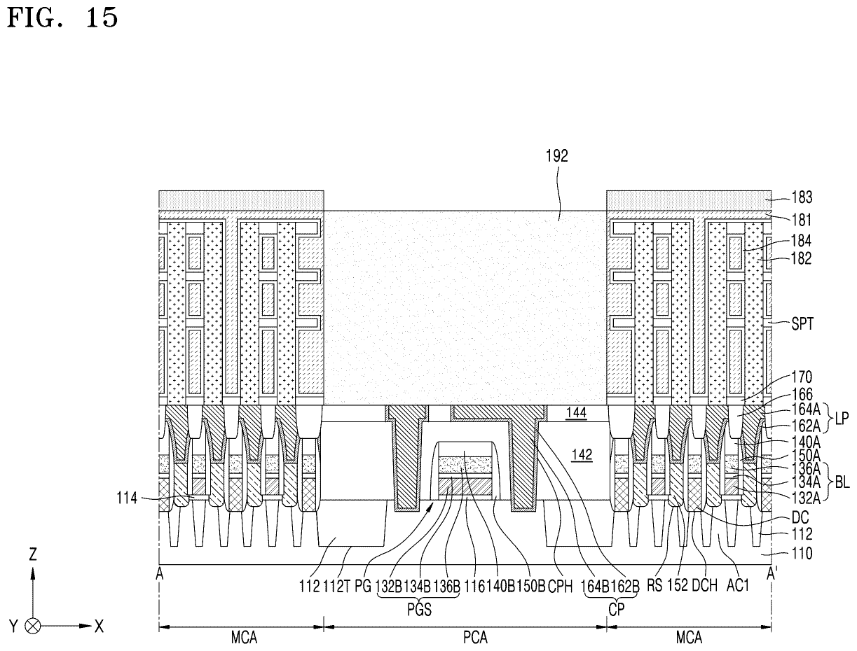

Referring to FIG. 15, the second mask pattern M2 (refer to FIG. 14) may be used as an etching mask to remove a portion of the metal material layer 183P (refer to FIG. 14) arranged in the peripheral circuit area PCA. A portion of the metal material layer 183P arranged in the peripheral circuit area PCA may be removed, thereby causing the upper surface of the interlayer insulating layer 192 to be exposed. In addition, the metal material layer 183P that is not removed and remains in the memory cell area MCA may be the metal plate layer 183 included in the second electrode 186 of the capacitor structure 180. In addition, a step difference may be generated between the memory cell area MCA in which the metal material layer 183P remains and the peripheral circuit area PCA where the metal material layer 183P is removed.

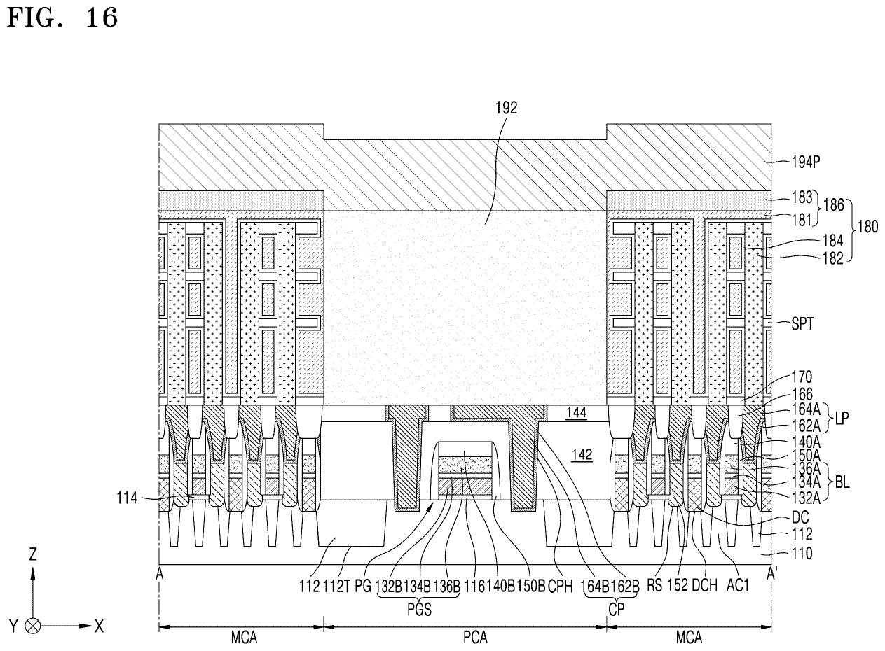

Referring to FIG. 16, a second insulating material layer 194P may cover the metal plate layer 183 in the memory cell area MCA and cover the interlayer insulating layer 192 in the peripheral circuit area PCA. The second insulating material layer 194P may be formed by the deposition process. In some embodiments, the second insulating material layer 194P may include TEOS, PE-TEOS, LD-TEOS, or a combination thereof. In some embodiments, the second insulating material layer 194P may include materials different from the first insulating material layer 192P (refer to FIG. 15). The second insulating material layer 194P may have a step difference in the memory cell area MCA and the peripheral circuit area PCA. For example, the upper surface of a portion of the second insulating material layer 194P arranged in the peripheral circuit area PCA may be arranged at a lower vertical level than the remaining portion of the second insulating material layer 194P in the memory cell area MCA.

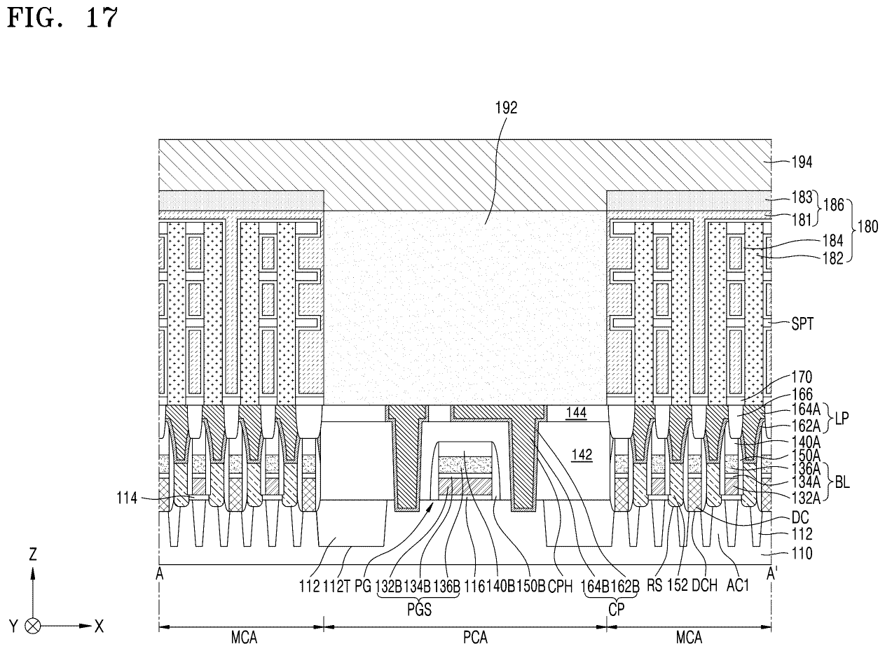

Referring to FIG. 17, the upper surface of the second insulating material layer 194P (refer to FIG. 16) may be planarized by the planarization process. The planarization process may be, for example, the chemical mechanical polishing (CMP) process. A portion of the second insulating material layer 194P may be removed by the planarization process and the remaining second insulating material layer 194P may be the capping insulating layer 194. Through the planarization process, the upper surface of the capping insulating layer 194 may be arranged on the same plane in the memory cell area MCA and the planarization process PCA.

As described with reference to FIGS. 11, 12, 16, and 17, the interlayer insulating layer 192 and the capping insulating layer 194 may respectively be formed through different processes. Thus, the interlayer insulating layer 192 and the capping insulating layer 194 may not be integral with one another and may be divided into separate membranes by a boundary between the interlayer insulating layer 192 and the capping insulating layer 194.

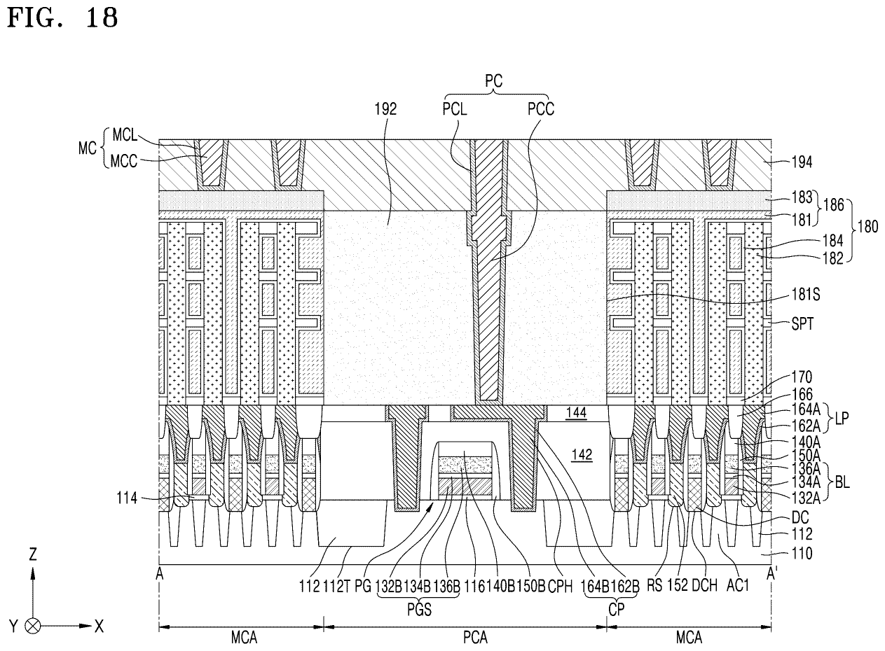

In some embodiments, the planarization process described with reference to FIG. 17 may be omitted. In this case, after the second insulating material layer 194P is formed as described with reference to FIG. 16, a contact forming process to be described with reference to FIG. 18 may be proceeded immediately such that the step difference of the second insulating material layer 194P is not removed. Thereafter, the semiconductor device 10b illustrated in FIG. 5 may be manufactured by performing subsequent processes.

Referring to FIG. 18, a plurality of metal contact holes (not shown) penetrating through the capping insulating layer 194 may be formed in the memory cell area MCA and the peripheral circuit contact hole (not shown) penetrating through the capping insulating layer 194 and the interlayer insulating layer 192 may be formed in the peripheral circuit area PCA. The plurality of metal contact holes may expose the upper surface of the metal plate layer 183, and the peripheral circuit contact hole may expose the upper surface of the contact plug CP. The plurality of metal contact holes and the peripheral circuit contact hole may be formed by an etching process. In this case, the peripheral circuit contact hole formed through the etching process may partially protrude in the horizontal direction in an area adjacent to the boundary between the capping insulating layer 194 and the interlayer insulating layer 192. The partial protrusion of the peripheral circuit contact hole in the horizontal direction may be caused due to the interlayer insulating layer 192 and the capping insulating layer 194, which are etching object layers of the etching process, being divided into separate layers, as shown in FIG. 17.

In some embodiments, according to conditions of the etching process, the peripheral circuit contact hole may be partially depressed in the horizontal direction in an area adjacent to the boundary between the capping insulating layer 194 and the interlayer insulating layer 192. In this case, the semiconductor device 10a shown in FIG. 4 may be manufactured by proceeding with the subsequent process to be described later.

Next, the cell conductive barrier layer MCL conformally covering the inner wall of the plurality of metal contact holes, and the peripheral circuit conductive barrier layer PCL conformally covering the inner wall of the peripheral circuit contact hole, may be formed. The cell conductive barrier layer MCL and the peripheral circuit conductive barrier layer PCL may include Ti, TiN, or a combination thereof, but are not limited thereto.

Subsequently, the cell contact conductive layer MCC filling the plurality of metal contact holes and the contact conductive layer peripheral circuit PCC filling the peripheral circuit contact hole may be formed, and the plurality of metal contacts MC and the peripheral circuit contact PC may be formed by polishing the upper portion of the cell conductive barrier layer MCL and the peripheral circuit conductive barrier layer PCL and the upper portion of the cell contact conductive layer MCC and the peripheral circuit contact conductive layer PCC.

Subsequently, in the result of FIG. 18, the semiconductor device 10 of FIGS. 1 to 3 may be manufactured by forming the upper wiring layer 196 and the interlayer insulating layer 198 on the peripheral circuit contact PC, the metal contact MC, and the capping insulating layer 194.

While inventive concepts have been particularly shown and described with reference to embodiments thereof, it will be understood that various changes in form and details may be made therein without departing from the spirit and scope of the following claims.

What is claimed is:

1. A semiconductor device comprising:
a substrate including a memory cell area with a first active area and a peripheral circuit area with a second active area;
a capacitor structure including a first electrode connected to the first active area in the memory cell area, a second electrode including a silicon containing layer surrounding the first electrode on the memory cell area and a metal plate layer on the silicon containing layer, and a capacitor dielectric layer between the first electrode and the second electrode;
an interlayer insulating layer on the peripheral circuit area; and
a capping insulating layer covering the capacitor structure on the memory cell area and covering the interlayer insulating layer on the peripheral circuit area, wherein
the metal plate layer is on an upper surface of the silicon containing layer and the metal plate layer is not on a side surface of the silicon containing layer.

2. The semiconductor device of claim 1, wherein a side surface of the metal plate layer and the side surface of the silicon containing layer are coplanar in a vertical direction.

3. The semiconductor device of claim 1, wherein the interlayer insulating layer covers the side surface of the silicon containing layer.

4. The semiconductor device of claim 1, wherein the upper surface of the interlayer insulating layer and the upper surface of the silicon containing layer are coplanar in a horizontal direction.

5. The semiconductor device of claim 1, wherein the capping insulating layer covers an upper surface and a side surface of the metal plate layer.

6. The semiconductor device of claim 1, wherein the upper surface of the silicon containing layer is flat.

7. The semiconductor device of claim 1, wherein an upper surface of the capping insulating layer is flat.

8. The semiconductor device of claim 1, wherein an upper surface of the capping insulating layer has a step difference between the memory cell area and the peripheral circuit area.

9. The semiconductor device of claim 8, wherein a vertical length of the step difference on the upper surface of the capping insulating layer is equal to a vertical length of the metal plate layer.

10. The semiconductor device of claim 8, further comprising:
a cell contact on the memory cell area, the cell contact penetrating through the capping insulating layer in a vertical direction and being connected to the metal plate layer; and
a peripheral circuit contact on the peripheral circuit area, the peripheral circuit contact penetrating through the capping insulating layer and the interlayer insulating layer in the vertical direction and being connected to the second active area, wherein
a level of an upper surface of the peripheral circuit contact is a lower vertical level than an upper surface of the cell contact.

11. The semiconductor device of claim 1, further comprising:
a peripheral circuit contact penetrating through the capping insulating layer and the interlayer insulating layer in a vertical direction and connecting to the second active area, wherein
the peripheral circuit contact partially protrudes in a horizontal direction in an area adjacent to a boundary between the capping insulating layer and the interlayer insulating layer.

12. The semiconductor device of claim 1, further comprising:
a peripheral circuit contact penetrating through the capping insulating layer and the interlayer insulating layer in a vertical direction and connecting to the second active area, wherein
the peripheral circuit contact is partially depressed in a horizontal direction in an area adjacent to a boundary between the capping insulating layer and the interlayer insulating layer.

13. A semiconductor device comprising:
a substrate including a memory cell area with a first active area and a peripheral circuit area with a second active area;
a capacitor structure including a first electrode connected to the first active area in the memory cell area, a second electrode including a silicon containing layer surrounding the first electrode on the memory cell area and a metal plate layer on the silicon containing layer, and a capacitor dielectric layer between the first electrode and the second electrode;
an interlayer insulating layer on the peripheral circuit area; and
a capping insulating layer covering the capacitor structure on the memory cell area and covering the interlayer insulating layer on the peripheral circuit area, wherein
an upper surface of the silicon containing layer and an upper surface of the interlayer insulating layer are coplanar in a horizontal direction.

14. The semiconductor device of claim 13, wherein
the metal plate layer is on the upper surface of the silicon containing layer and the metal plate layer is not on a side surface of the silicon containing layer, and
the interlayer insulating layer covers the side surface of the silicon containing layer.

15. The semiconductor device of claim 13, wherein a side surface of the metal plate layer and the side surface of the silicon containing layer are coplanar in a vertical direction.

16. The semiconductor device of claim 13, wherein the capping insulating layer covers an upper surface of the metal plate layer and a side surface of the metal plate layer.

17. The semiconductor device of claim 1, wherein the upper surface of the silicon containing layer and an upper surface of the capping insulating layer are each flat.

18. The semiconductor device of claim 13, wherein
the upper surface of the capping insulating layer has a step difference between the memory cell area and the peripheral circuit area, and
a length of the step difference on the upper surface of the capping insulating layer in a vertical direction is equal to a length of the metal plate layer in the vertical direction.

19. The semiconductor device of claim 18, further comprising:
a cell contact on the memory cell area, the cell contact penetrating through the capping insulating layer in a vertical direction and being connected to the metal plate layer; and
a peripheral circuit contact on the peripheral circuit area, the peripheral circuit contact penetrating through the capping insulating layer and the interlayer insulating layer in the vertical direction and being connected to the second active area, wherein
a level of an upper surface of the peripheral circuit contact is arranged at a lower vertical level than an upper surface of the cell contact.

20. A semiconductor device comprising:
a substrate including a memory cell area with a first active area and a peripheral circuit area with a second active area;
a capacitor structure including a first electrode connected to the first active area in the memory cell area, a second electrode including a silicon germanium layer surrounding the first electrode on the memory cell area and a metal plate layer on the silicon germanium layer, and a capacitor dielectric layer between the first electrode and the second electrode;
an interlayer insulating layer on the peripheral circuit area and covering a side surface of the capacitor structure; and
a capping insulating layer covering the capacitor structure on the memory cell area and covering the interlayer insulating layer on the peripheral circuit area, wherein
the metal plate layer is on an upper surface of the silicon germanium layer and the metal plate layer is not on a side surface of the silicon germanium layer, and
the upper surface of the silicon germanium layer and an upper surface of the interlayer insulation layer are coplanar.
